(19) United States
(12) Patent Application Publication
(10) Pub. No.: US 2026/0343740 A1
(43) Pub. Date: Oct. 29, 2026

(54) PRINTED CIRCUIT BOARD AND MANUFACTURING METHOD THEREOF

(71) Applicant: SAMSUNG ELECTRO-MECHANICS CO., LTD., Suwon-si (KR)

(72) Inventors: Chanhoon Ko, Suwon-si (KR); Sanghoon Kim, Suwon-si (KR); Youngil Cho, Suwon-si (KR)

(73) Assignee: SAMSUNG ELECTRO-MECHANICS CO., LTD., Suwon-si (KR)

(21) Appl. No.: 19/417,032

(22) Filed: Dec. 11, 2025

(30) Foreign Application Priority Data
Apr. 28, 2025 (KR) 10-2025-0055367
Jul. 14, 2025 (KR) 10-2025-0094393

(51) Int. Cl. H05K 1/11; H05K 3/40; H05K 3/46

(52) U.S. Cl. CPC H05K 1/112; H05K 3/4038; H05K 3/4682; H05K 2201/09472; H05K 2201/096

(57) ABSTRACT

A printed circuit board according to the present disclosure may include an insulating layer, a connection pad with a side surface embedded in the insulating layer, a protruding pattern disposed on an upper surface of the connection pad and integral with the connection pad, and a solder resist layer disposed on the insulating layer and covering at least a portion of the upper surface of the connection pad and at least a portion of a side surface of the protruding pattern.

### CROSS-REFERENCE TO RELATED APPLICATION

This application claims priority to and the benefit of Korean Patent Application No. 10-2025-0055367 filed with the Korean Intellectual Property Office on Apr. 28, 2025, and Korean Patent Application No. 10-2025-0094393 filed with the Korean Intellectual Property Office on Jul. 14, 2025, the entire contents of which are incorporated herein by reference.

### BACKGROUND

### a Technical Field

The present disclosure relates to a printed circuit board and a manufacturing method thereof.

### b Description of the Related Art

A printed circuit board may be used as a board for mounting electronic components.

With the recent development of 3G, 4G, 5G, and more high-speed communication and artificial intelligence (AI) technologies, highly integrated printed circuit board that implements related electronic components can be used. The electronic components may include a semiconductor chip, an antenna, an inductor, a capacitor, a filter, and the like. For example, a plurality of the electronic components are mounted on a single printed circuit board, so that various and complex product functions can be implemented while reducing the mounting space, thereby miniaturizing and thinning the printed circuit board.

As the printed circuit board is miniaturized and thinned as described above, the miniaturization of I/O connection pads and circuit patterns included in the printed circuit boards is required. Since the printed circuit board is recently used in fields that require a high level of reliability, it is necessary to provide the printed circuit board with improved structural stability and reliability while including fine circuit patterns and integrated connection structures.

### SUMMARY

An embodiment of the present disclosure attempts to provide a printed circuit board with improved structural stability and space efficiency.

Another embodiment of the present disclosure attempts to provide a manufacturing method of a printed circuit board with improved structural stability and space efficiency.

A printed circuit board according to an embodiment of the present disclosure may include an insulating layer, a connection pad with a side surface embedded in the insulating layer, a protruding pattern disposed on a first surface of the connection pad and integral with the connection pad, and a solder resist layer disposed on the insulating layer, and covering at least a portion of the first surface of the connection pad and at least a portion of a side surface of the protruding pattern.

A second surface of the connection pad may directly contact the insulating layer.

At least a portion of the first surface of the connection pad may be not embedded in the insulating layer.

A length from a second surface of the connection pad to a first surface of the protruding pattern in a thickness direction perpendicular to a first surface of the insulating layer may be greater than a length from the second surface of the connection pad to the first surface of the insulating layer.

A width of the protruding pattern may be less than or equal to a width of the connection pad.

A ratio of the width of the protruding pattern to the width of the connection pad may be 0.9 to 1.0.

A metal barrier layer may be disposed between the first surface of the connection pad and the solder resist layer, and between the side surface of the protruding pattern and the solder resist layer.

The metal barrier layer may be further disposed on a first surface of the protruding pattern.

A length from a second surface of the connection pad to the first surface of the connection pad in a thickness direction perpendicular to a first surface of the insulating layer may be less than or equal to a length from the second surface of the connection pad to the first surface of the insulating layer.

A first surface of the insulating layer and the first surface of the connection pad may be disposed at the same level.

A metal barrier layer may be disposed only (i) between the first surface of the connection pad and the solder resist layer, and (ii) between the side surface of the protruding pattern and the solder resist layer.

A manufacturing method of a printed circuit board according to an embodiment of the present disclosure may include forming a dummy layer on a carrier substrate, the dummy layer defining a cavity that exposes a portion of the carrier substrate, forming a metal barrier layer on the dummy layer, and the portion of the carrier substrate, forming: a protruding pattern filling the cavity, and a first wiring layer including a connection pad, where the connection pad and the protruding pattern may be formed together on the metal barrier layer, forming a build-up structure on the dummy layer and the first wiring layer, the build-up structure including an insulating layer and an inner wiring layer, separating the build-up structure and the dummy layer from the carrier substrate, removing the dummy layer, and forming a solder resist layer covering at least a portion of a first surface of the connection pad and at least a portion of a side surface of the protruding pattern on a first surface of the insulating layer.

After the forming of the protruding pattern and the first wiring layer, an exposed portion of the metal barrier layer may be removed.

After the removing of the dummy layer and before the forming the solder resist layer, the metal barrier layer may be removed.

After the forming of the solder resist layer, the exposed portion of the metal barrier layer may be removed.

The first surface of the insulating layer and the first surface of the connection pad may be disposed at the same level.

The connection pad and the protruding pattern may be formed integrally through a single process.

According to an embodiment of the present disclosure, alignment between the protruding pattern and the connection pad may be improved, thereby improving structural stability and reliability of the printed circuit board.

According to an embodiment of the present disclosure, an increase in the size of the connection pad and the protruding pattern may be suppressed, and a fine pitch may be implemented.

According to an embodiment of the present disclosure, the surface roughness of the protruding pattern and the first wiring layer can be reduced, and the speed of signal transmission of the printed circuit board can be further improved.

According to an embodiment of the present disclosure, electronic components can be mounted more stably on the printed circuit board, and warpage and/or distortion of the printed circuit board can be more suppressed.

However, the problems to be solved by the embodiments are not limited to those described above, and can be variously extended within the scope of the technical ideas included in the embodiments.

### BRIEF DESCRIPTION OF THE DRAWINGS

FIG. 1 is a perspective view illustrating a printed circuit board according to an embodiment.

FIG. 2 is a cross-sectional view of the printed circuit board according to an embodiment taken along line I-I' of FIG. 1.

FIG. 3 is a cross-sectional view of the printed circuit board according to another embodiment taken along line I-I' of FIG. 1.

FIGS. 4-17 are cross-sectional views illustrating a manufacturing method of a printed circuit board according to an embodiment.

FIGS. 18-19 are cross-sectional views illustrating a manufacturing method of a printed circuit board according to another embodiment.

FIG. 20 is cross-sectional view illustrating a manufacturing method of a printed circuit board according to still another embodiment.

FIGS. 21-26 are cross-sectional views illustrating a manufacturing method of a printed circuit board according to still another embodiment.

### DETAILED DESCRIPTION

Hereinafter, various embodiments of the present disclosure will be described in detail so that a person of ordinary skill in the technical field to which the present disclosure belongs can easily implement it with reference to the accompanying drawings. In order to clearly describe the present disclosure, parts unrelated to the description are omitted in the drawings, and the same reference numerals are designated to the same or similar elements throughout the specification. In addition, some components in the drawings may be exaggerated, omitted, or schematically illustrated, and the size of each component may not entirely reflect the actual size.

The accompanying drawings are provided only in order to allow embodiments disclosed in the present specification to be easily understood and are not to be interpreted as limiting the concept disclosed in the present specification, and it is to be understood that the present disclosure includes all modifications, equivalents, and substitutions without departing from the scope and concept of the present disclosure.

Terms including ordinal numbers such as first, second, and the like will be used only to describe various components and are not to be interpreted as limiting these components. The terms are only used to differentiate one component from other components.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Furthermore, in the specification, the word “on” or “above” means positioned on or below the object portion, and does not necessarily mean positioned on the upper side of the object portion based on a gravitational direction.

It will be further understood that terms "comprises/includes” or “have” used throughout the specification specify the presence of stated features, numerals, steps, operations, components, parts, or a combination thereof, but do not preclude the presence or addition of one or more other features, numerals, steps, operations, components, parts, or a combination thereof. Accordingly, unless explicitly described to the contrary, the word “comprise” and variations such as “comprises” or “comprising” will be understood to imply the inclusion of stated components but not the exclusion of any other components.

Further, throughout the specification, the phrase “in a plan view” means when an object portion is viewed from above, and the phrase “in a cross-sectional view” means when a cross-section taken by vertically cutting an object portion is viewed from the side.

In addition, throughout the specification, "connected" means that two or more components are not only directly connected, but two or more components may be connected indirectly through other components, physically connected as well as being electrically connected, or it may be referred to by different names depending on the location or function but may mean integral.

The lengths and widths disclosed herein may be measured by a scanning electron microscope (SEM). Other methods and/or tools appreciated by one of ordinary skill in the art, even if not described in the present disclosure, may also be used.

Hereinafter, embodiments will be described with reference to the drawings.

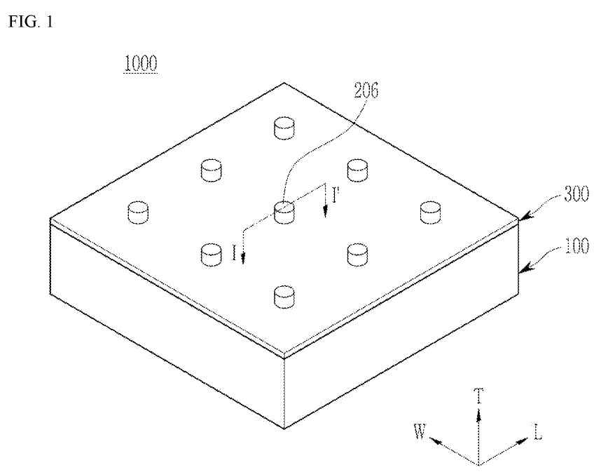

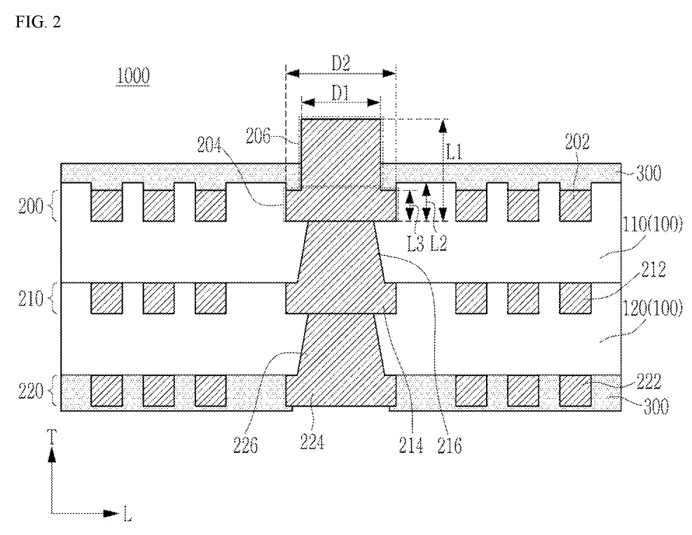

FIG. 1 is a perspective view illustrating a printed circuit board according to an embodiment. FIG. 2 is a cross-sectional view of the printed circuit board taken along line I-I' of FIG. 1.

The L-axis, W-axis, and T-axis shown in the drawings respectively indicate the length direction, width direction, and thickness direction of the printed circuit board 1000 and an insulating layer 100 .

The thickness direction(T-axis direction) may indicate a direction substantially perpendicular to an upper surface (e.g., first surface) of the insulating layer 100. For example, the thickness direction may indicate a direction in which a first sub-insulating layer 110 and the second sub-insulating layer 120 included in the insulating layer 100 are stacked.

The length direction(L-axis direction) and the width direction(W-axis direction) may be parallel to the upper surface of the insulating layer 100, respectively. The length direction and the width direction may be approximately perpendicular to each other on a plane parallel to the upper surface of the insulating layer 100, and may be approximately perpendicular to the thickness direction, respectively. In one example, the length of the

printed circuit board 1000 or the insulating layer 100 in the length direction may be greater than the length in the width direction.

Referring to FIGS. 1 and 2, the printed circuit board 1000 according to an embodiment may include the insulating layer 100, a first wiring layer 200 including a first circuit wiring 202 and a connection pad 204, a protruding pattern 206 disposed on an upper surface (e.g., first surface) of the connection pad 204, and a solder resist layer 300 disposed on the insulating layer 100. The first circuit wiring 202 and the connection pad 204 may be disposed on the same layer or at the same level.

The insulating layer 100 may include a plurality of sub-insulating layers 110 and 120. In an example, the insulating layer 100 may include the first sub-insulating layer 110 and the second sub-insulating layer 120 that are sequentially stacked. An upper surface of the first sub-insulating layer 110 may be provided as the upper surface of the insulating layer 100, and a lower surface of the second sub-insulating layer 120 may be provided as a lower surface of the insulating layer 100.

At least a portion of the first wiring layer 200 may be embedded in the first sub-insulating layer 110.

The printed circuit board 1000 may further include a second wiring layer 210 disposed on a lower surface of the first sub-insulating layer 110 and embedded in the second sub-insulating layer 120, and a third wiring layer 220 disposed on the lower surface of the second sub-insulating layer 120.

The second wiring layer 210 may include a second circuit wiring 212 and an internal pad 214. The third wiring layer 220 may include a third circuit wiring 222 and a lower pad 224.

The second circuit wiring 212 and the internal pad 214 may be disposed on the same layer or at the same level. The third circuit wiring 222 and the lower pad 224 may be disposed on the same layer or at the same level.

The circuit wirings 202, 212, and 222 disposed on different layers may be electrically connected to each other through a circuit via (not shown).

The printed circuit board 1000 may further include a first via 216 penetrating the first sub-insulating layer 110 and connecting the connection pad 204 and the internal pad 214. The printed circuit board 1000 may further include a second via 226 penetrating the second sub-insulating layer 120 and connecting the internal pad 214 and the lower pad 224.

One end of any of the plurality of the first circuit wirings 202 may be provided as the connection pad 204. One end of any of the plurality of the second circuit wirings 212 may be provided as the internal pad 214. One end of any of the plurality of the third circuit wirings 222 may be provided as the lower pad 214.

The insulating layer 100 may include an Ajinomoto Build-up Film (ABF). In an example, at least one of the insulating layer 100 may include a prepreg manufactured by impregnating glass fibers with a thermosetting resin or a thermoplastic resin. In another example, at least one of the insulating layer 100 may include a photo-imageable dielectric (PID).

Although FIG. 2 illustrates that the insulating layer 100 includes two sub-insulating layers 110 and 120, three or more sub-insulating layers may be included depending on the design of the printed circuit board 1000. In this case, circuit wirings and pads are also disposed on each sub-insulating layer, and vias that penetrate the sub- insulating layers and connect pads or circuit wirings on different sub-insulating layers may exist.

The printed circuit board 1000 according to the present disclosure may include an embedded trace substrate (ETS) structure. A side surface of the connection pad 204 may be embedded in the insulating layer 100, for example, the first sub-insulating layer 110. Accordingly, the thickness of the printed circuit board 1000 is reduced, and an area of a pad exposed to the outside is reduced, thereby further improving structural stability.

At least a portion of the upper surface of the connection pad 204 may not be embedded in the insulating layer 100. For example, at least a portion of the upper surface of the connection pad 204 may be exposed to the upper surface of the insulating layer 100.

A lower surface (e.g., second surface) of the connection pad 204 may be in direct contact with the insulating layer 100. Since the connection pad 204 is directly disposed on the insulating layer 100 without a separate seed metal layer, space efficiency may be further improved and interface stability and driving reliability may be further improved.

The protruding pattern 206 may extend from the upper surface of the connection pad 204 in the thickness direction (T-axis direction).

According to one example of the present disclosure, the protruding pattern 206 may be integral with the connection pad 204. For example, the protruding pattern 206 may be formed of the same material as the connection pad 204 through a single process, for example, plating. Accordingly, alignment between the protruding pattern 206 and the connection pad 204 may be improved, thereby improving the structural stability and reliability of the printed circuit board 1000. In addition, since a via connecting the protruding pattern 206 and the connecting pad 204 is unnecessary, the size increase of the connecting pad 204 and the protruding pattern 206 due to the processing of the via hole can be suppressed and a fine pitch can be implemented. Accordingly, a width D1 of the protruding pattern 206 may be reduced. In an example, the width D1 of the protruding pattern 206 may be about 20µm to 51µm.

Since the protruding pattern 206 and the connection pad 204 are integrally formed, there may be substantially no defects such as hairline, dimple, and crack between the protruding pattern 206 and the connection pad 204. Therefore, the driving reliability of the printed circuit board 1000 may be improved. The expression "substantially no defects " in the present disclosure includes the presence of only a very small amount, which is difficult to observe or analyze by ordinary analytical means.

In the thickness direction, the length L1 from the lower surface of the connection pad 204 to an upper surface (e.g., first surface) of the protruding pattern 206 may be greater than a length L2 from the lower surface of the connection pad 204 to the upper surface of the insulating layer 100. The protruding pattern 206 may protrude above the upper surface of the insulating layer 100 to be connected to an electronic component mounted on the printed circuit board 1000. For example, the protruding pattern 206 may be provided as an outermost connection pad of the printed circuit board 1000. Therefore, the electronic component may be electrically connected to the connection pad 204 through the protruding pattern 206.

The width D1 of the protruding pattern 206 may be less than or equal to a width D2 of the connection pad 204. Accordingly, various pitches between a plurality of protruding patterns 206 may be implemented, thereby further improving the design flexibility of the printed circuit board 1000.

The width D1 of the protruding pattern 206 may represent the length of the longest line segment among line segments connecting two points located around the upper surface of the protruding pattern 206 and passing through the center point of the upper surface of the protruding pattern 206. When the upper surface of the protruding pattern 206 is circular, the width D1 of the protruding pattern 206 may represent a diameter of a circle. When the upper surface of the protruding pattern 206 is elliptical, the width D1 of the protruding pattern 206 may represent the length of a major axis passing through the center point of the ellipse. When the upper surface of the protruding pattern 206 is a polygon, the width D1 of the protruding pattern 206 may represent the length of the longest diagonal among the diagonal lines passing through the center point of the polygon.

The width D2 of the connection pad 204 may represent the length of the longest line segment among line segments connecting two points located around the upper surface of the connection pad 204 and passing through the center point of the upper surface of the connection pad 204. When the upper surface of the connection pad 204 is circular, the width D2 of the connection pad 204 may represent a diameter of a circle. When the upper surface of the connection pad 204 is elliptical, the width D2 of the connection pad 204 may represent a length of a major axis passing through the center point of the ellipse. When the upper surface of the connection pad 204 is a polygon, the width D2 of the connection pad 204 may represent a length of the longest diagonal among the diagonal lines passing through the center point of the polygon.

The width D1 of the protruding pattern 206 may be measured from a scanning electron microscope (SEM) analysis image obtained by photographing the printed circuit board 1000 in the thickness direction on the upper surface of the printed circuit board 1000. The width D1 according to the above-described definition of the protruding pattern 206 may be measured in the SEM analysis image. When the printed circuit board 1000 includes a plurality of protruding patterns 206, the width D1 of the protruding pattern 206 may be obtained by measuring the widths according to the above-described definition of the plurality of protruding patterns 206, respectively, and averaging the measured widths.

The width D2 of the connection pad 204 may be measured from an SEM analysis image obtained by polishing the upper surface of the printed circuit board 1000 in the thickness direction so that the entire upper surface of the connection pad 204 is exposed, and photographing the printed circuit board 1000 on the upper surface of the printed circuit board 1000 in the thickness direction. The width D2 according to the above-described definition of the connection pad 204 may be measured in the SEM analysis image. When the printed circuit board 1000 includes a plurality of connection pads 204, the width D2 of the connection pad 204 may be obtained by measuring the widths according to the above-described definition of the plurality of connection pads 204, respectively, and averaging the measured widths.

As illustrated in FIG. 2, in the thickness direction, a length L3 from the lower surface of the connection pad 204 to the upper surface of the connection pad 204 may be less than or equal to the length L2 from the lower surface of the connection pad 204 to the upper surface of the insulating layer 100. Accordingly, a short circuit caused by exposure of the first circuit wiring 202 may be suppressed, and reliability of the printed circuit board 1000 may be further improved.

In an example, the length L1-L3 of the protruding pattern 206 in the thickness direction may be about 20µm to about 51µm. In the range, as electronic component is stably mounted on the protruding pattern 206, the stability of the printed circuit board 1000 may be further improved.

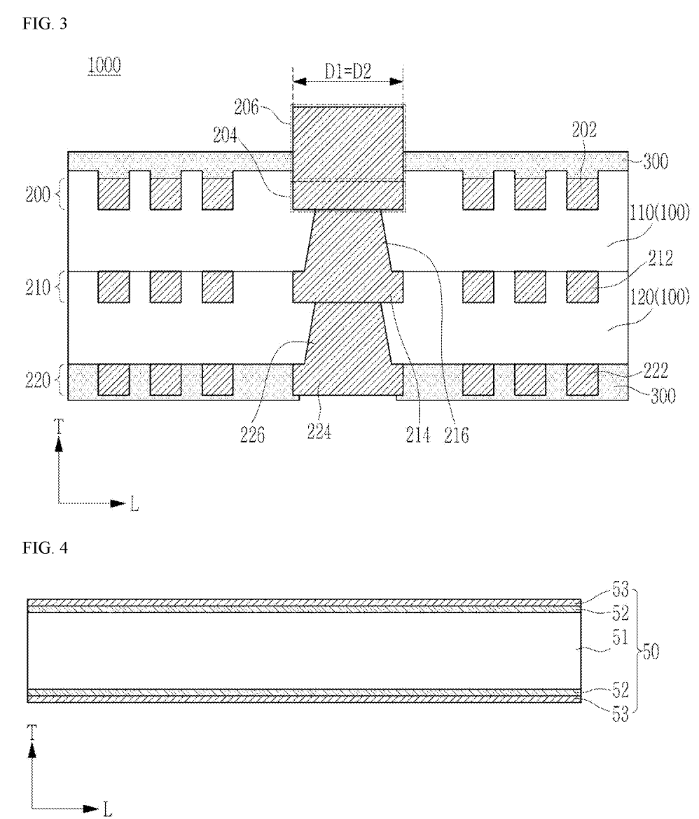

FIG. 3 is a cross-sectional view of the printed circuit board according to another embodiment taken along line I-I' of FIG. 1.

As described above, the protruding pattern 206 and the connection pad 204 may be integrally formed. Accordingly, while structural stability between the protruding pattern 206 and the connection pad 204 is improved, the width D2 of the connection pad 204 may be relatively reduced.

Referring to FIG. 3, the width D1 of the protruding pattern 206 may be substantially the same as the width D2 of the connecting pad 204. The expression "substantially the same" in the present specification may include a case in which the ratio (D1/D2) of the two lengths is 0.9 to 1.0.

In an example of the present disclosure, the solder resist layer 300 may be disposed on the insulating layer 100 and may cover at least a portion of the upper surface of the connection pad 204 and at least a portion of the sidewall of the protruding pattern 206. Accordingly, while the connection pad 204 is protected from external impact, the upper surface of the protruding pattern 206 may be exposed to contact the electronic component.

The solder resist layer 300 may further cover the first circuit wiring 202. Accordingly, the first wiring layer 200 may be protected from external contamination or impact as a whole.

The solder resist layer 300 may be further disposed on the lower surface of the insulating layer 100 (for example, the lower surface of the second sub-insulating layer 120). In this case, the solder resist layer 300 may cover the third circuit wiring 222 and may cover at least a portion of the lower surface of the lower pad 224. Accordingly, while the third circuit wiring 222 is protected from external contamination or impact, a portion of the lower surface of the lower pad 224 may be exposed. For example, the upper surface of the insulating layer 100 to which the protruding pattern 206 is exposed may be a surface facing the electronic component, and the lower surface of the insulating layer 100 to which the lower pad 224 is exposed may be a surface facing the mother board on which the printed circuit board 1000 is mounted. In this case, the printed circuit board 1000 may be connected to the mother board through the lower pad 224.

The solder resist layer 300 may cover the upper surface of the connection pad 204 exposed to the upper surface of the insulating layer 100, and may cover at least a portion of the sidewall of the protruding pattern 206. Accordingly, the reliability and signal concentration of the printed circuit board 1000 may be further improved by exposing only the protruding pattern 206 of the metal structure to the outside.

The solder resist layer 300 may include a known solder resist material, a thermosetting resin, and a material (e.g., ABF) including an inorganic filler. These may be used alone or in combination of two or more.

The above-described wiring layers 200, 210, and 220, the protruding pattern 206, and the vias 216 and 226 may include copper (Cu), aluminum (Al), silver (Ag), tin (Sn), gold (Au), nickel (Ni), lead (Pb), titanium (Ti), alloys thereof, and the like. These may be used alone or in combination of two or more. In an example, the wiring layers 200, 210, and 220, the protruding pattern 206, and the vias 216 and 226 described above may include copper (Cu). Accordingly, while electrical conductivity is improved, processability may be improved.

Hereinafter, a manufacturing method of the printed circuit board 1000 described above with reference to the drawings will be described in detail.

FIGS. 4-17 are cross-sectional views illustrating a manufacturing method of a printed circuit board according to an embodiment.

Referring to FIG. 4, a carrier substrate 50 may be prepared.

The carrier substrate 50 may include a core 51, a release layer 52 disposed on one or both surfaces of the core 51, and a seed metal layer 53 disposed on the release layer 52.

The core 51 may be a Detached Carrier Film and may include, for example, Copper Clad Laminate (CCL) and the like. In this case, the core 51 may include a core layer containing a prepreg manufactured by impregnating glass fibers with thermosetting resin or thermoplastic resin, and a copper foil layer formed on one or both sides of the core layer above. The release layer 52 may be disposed on the copper foil layer.

The release layer 52 may be formed using a known material for easy separation of the carrier board 50 and the printed circuit board 1000.

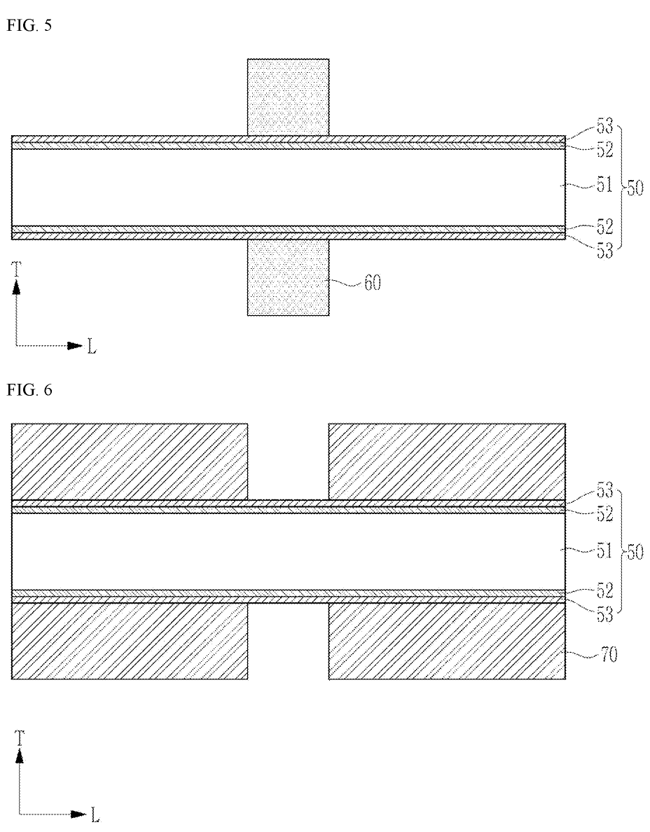

Referring to FIG. 5, a first photoresist 60 may be patterned on the seed metal layer 53. For example, the first photoresist 60 may be patterned through a photolithography process. In an example, the first photoresist 60 may be patterned to have substantially the same shape and size as the protruding pattern 206.

Referring to FIG. 6, a dummy layer 70 may be formed on the seed metal layer 53 by using the first photoresist 60. For example, the dummy layer 70 may be a metal layer. In this case, the dummy layer 70 may be formed through a plating process using the seed metal layer 53 as a seed.

After the dummy layer 70 is formed, the first photoresist 60 may be removed.

The dummy layer 70 may define a cavity exposing a portion of the carrier substrate 50. The cavity may be defined by an exposed surface of the carrier substrate 50 and a side surface of the dummy layer 70. Through the cavity, the dummy layer 70 may be provided as a mold or a template for forming the protruding pattern 206.

The seed metal layer 53 and the dummy layer 70 may include the same material. For example, the seed metal layer 53 and the dummy layer 70 may include the same metal as the protruding pattern 206, the wiring layers 200, 210, and 220, and the vias 216 and 226.

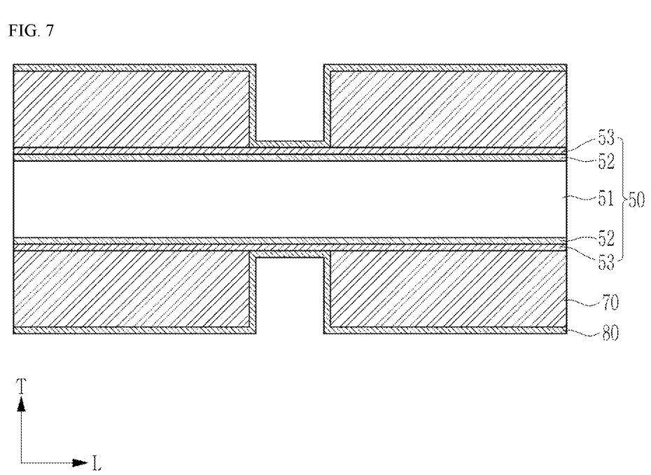

Referring to FIG. 7, a metal barrier layer 80 may be formed on the portion of the carrier substrate 50 exposed by the cavity and the dummy layer 70. For example, the metal barrier layer 80 may be formed through electroless plating. The electroless plating may be performed by reducing and depositing metal ions in the solution onto the dummy layer 70. In another example, the metal barrier layer 80 may be formed through electroplating. The electroplating may be performed by reducing a metal on the dummy layer 70 by applying a current through an external power source.

The metal barrier layer 80 may be provided as a temporary protective layer of the protruding pattern 206 and the first wiring layer 200 during the manufacturing process of the printed circuit board 1000. Through the metal barrier layer 80, the surface roughness of the protruding pattern 206 and the first wiring layer 200 may be reduced, and the signal transmission speed of the printed circuit board 1000 may be further improved.

The metal barrier layer 80 may include nickel (Ni), silver (Ag), gold (Au), platinum (Pt), palladium (Pd), and the like. These may be used alone or in combination of two or more. The metal barrier layer 80 may include a different metal from the dummy layer 70, the protruding pattern 206, and the first wiring layer 200. In one example, the metal barrier layer 80 may be a Ni layer.

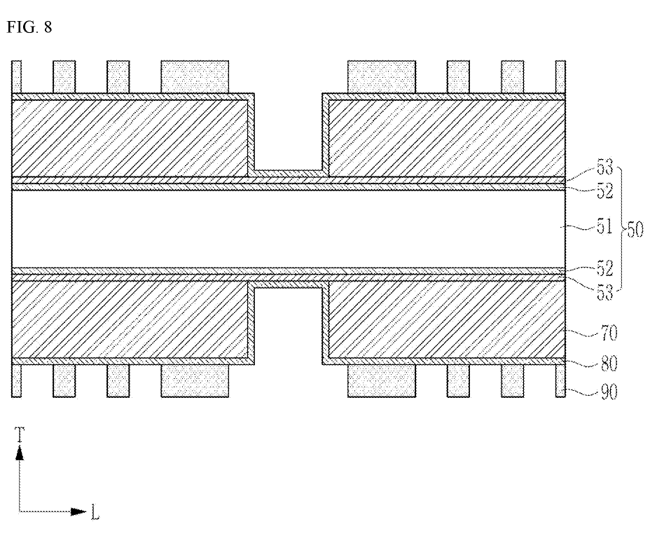

Referring to FIG. 8, a second photoresist 90 may be patterned on the metal barrier layer 80. For example, the second photoresist 90 may be patterned through a photolithography process.

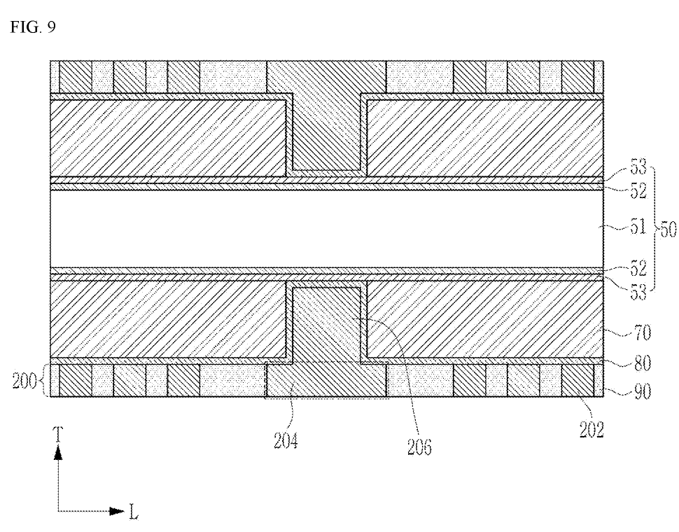

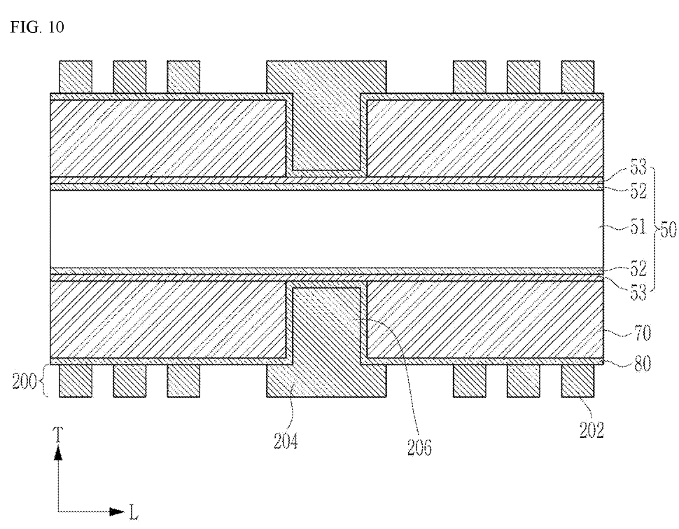

Referring to FIG. 9, the protruding pattern 206 and the first wiring layer 200 may be formed together using the dummy layer 70 and the second photoresist 90 as a frame or mold, for example, a plating mask. In an example, the protruding pattern 206 and the first wiring layer 200 may be formed by performing electroplating using the metal barrier layer 80 as a seed layer on a portion where the second photoresist 90 is not formed. The protruding pattern 206 may be formed to fill the cavity. Referring to FIG. 10, the second photoresist 90 may be removed after the protruding pattern 206 and the first wiring layer 200 are formed.

The first wiring layer 200 may include the first circuit wiring 202 and the connection pad 204, and the connection pad 204 and the protruding pattern 206 may be integrally formed through a single process. Accordingly, as described above, alignment of the connection pad 204 and the protruding pattern 206 may be improved, and the width D1 of the protruding pattern 206 and the width D2 of the connecting pad 204 may be reduced. Accordingly, while structural stability of the printed circuit board 1000 is improved, a fine pitch structure may be implemented.

In addition, since the protruding pattern 206 and the first wiring layer 200 are formed together in one process, step difference in the thickness direction between the plurality of protruding patterns 206 may be reduced. Therefore, electronic components may be more stably mounted on the printed circuit board 1000, and warpage and/or distortion of the printed circuit board 1000 may be further suppressed.

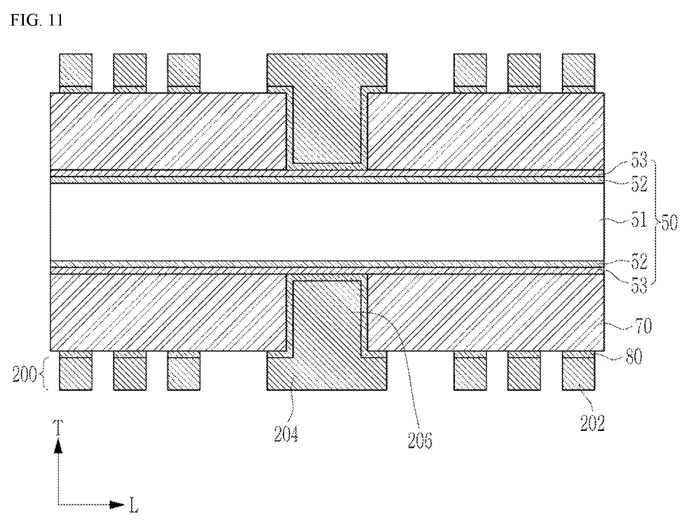

Referring to FIG. 11, after the first wiring layer 200 and the protruding pattern 206 are formed, a portion of the metal barrier layer 80 exposed to the outside may be removed. For example, after the first wiring layer 200 and the protruding pattern 206 are formed, an etchant may be used to selectively remove an externally exposed portion of the metal barrier layer 80.

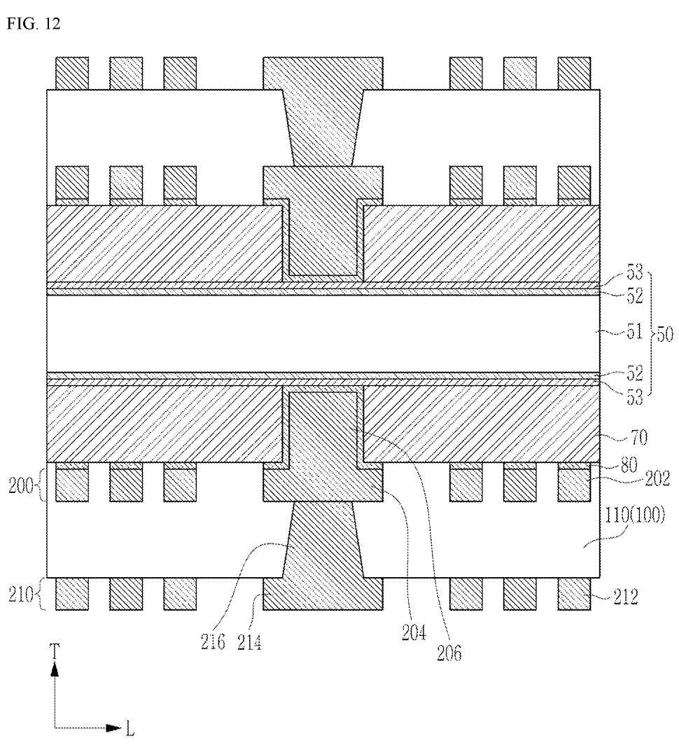

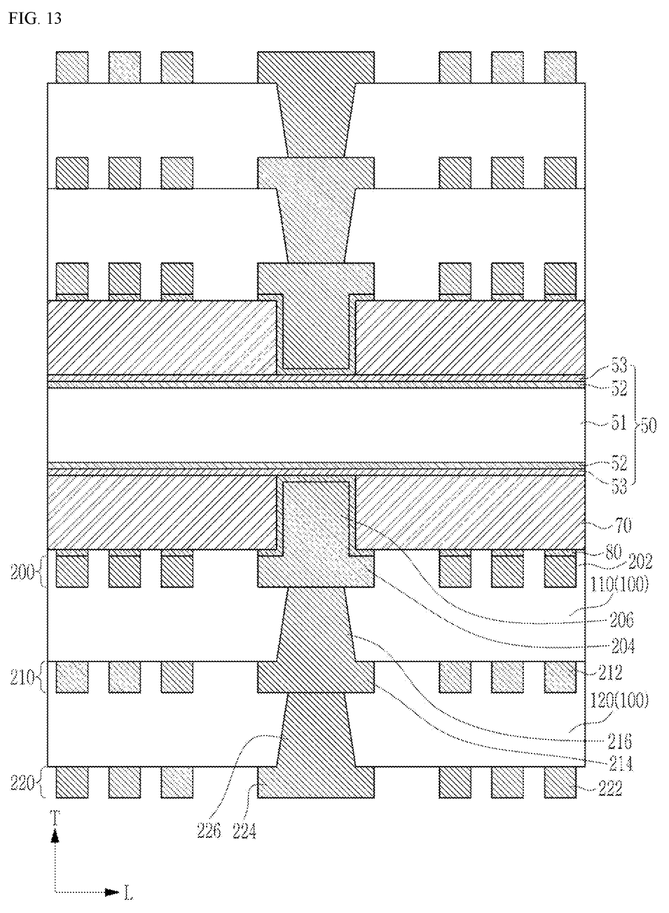

Referring to FIGS. 12 and 13, a build-up structure including an insulating layer 100 and other wiring layers 210 and 220 may be formed on the dummy layer 70 and the first wiring layer 200.

In one example, the build-up structure may include an insulating layer 100 including a plurality of sub-insulating layers 110 and 120 and other wiring layers 210 and 220 disposed on one surface of each of the sub-insulating layers 110 and 120.

For convenience of explanation, in this specification, a stack structure of insulating layer 100 including the sub-insulating layers 110 and 120, wiring layers including the second wiring layer 210 and the third wiring layer 220, and the vias 216 and 226 is defined as a build-up structure.

According to an example, via holes penetrating each of the sub-insulating layers 110 and 120 through a drill or laser may be formed. The first via 216, the internal pad 214, the second via 226, and the lower pad 224 may be plated from inside the via holes.

The protruding pattern 206, the wiring layers 200, 210, and 220, and the vias 216 and 226 may be formed through a wiring formation process such as Additive Process (AP), Semi AP (SAP), Modified SAP (MSAP), and Tenting (TT). These may be used alone or in combination of two or more.

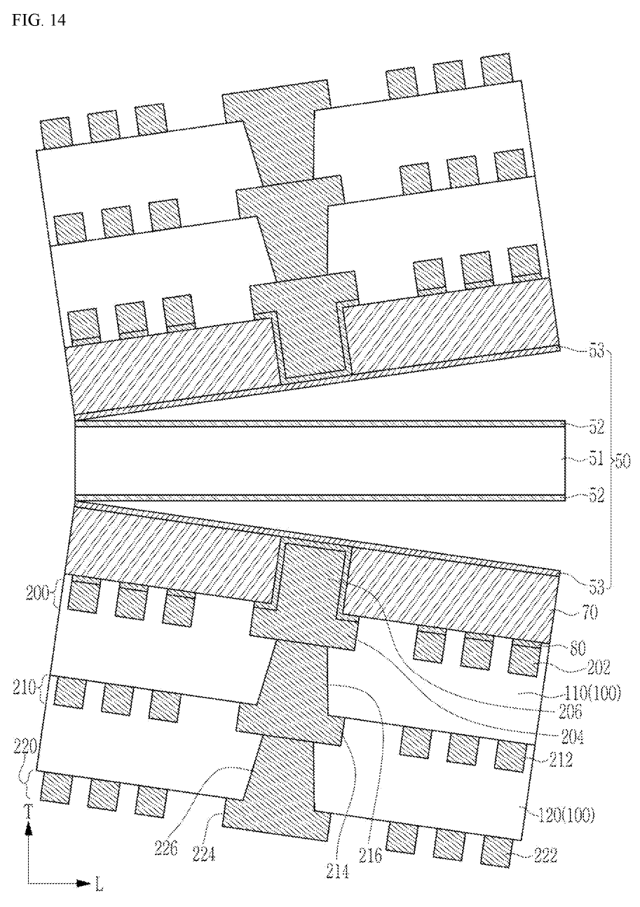

Referring to FIG. 14, the build-up structure may be separated from the carrier substrate 50 by separating the release layer 52 and the seed metal layer 53.

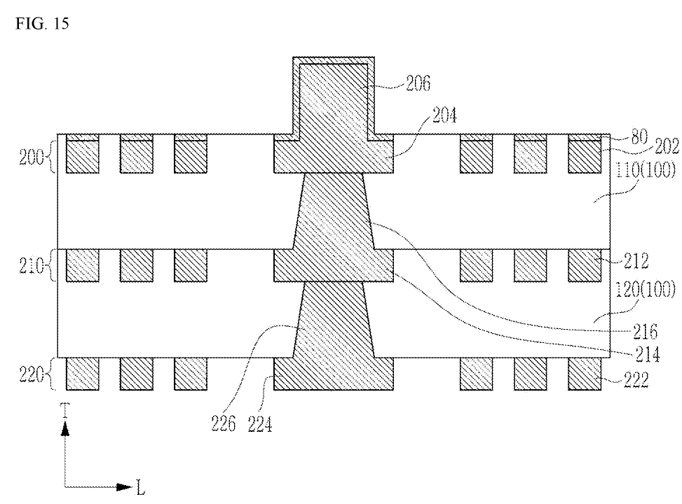

Referring to FIG. 15, the dummy layer 70 may be removed. In an example, the seed metal layer 53 and the dummy layer 70 may be removed together.

The dummy layer 70 and the seed metal layer 53 may be selectively removed using an etchant. The protruding pattern 206 and the first wiring layer 200 may be protected in the etching by the metal barrier layer 80.

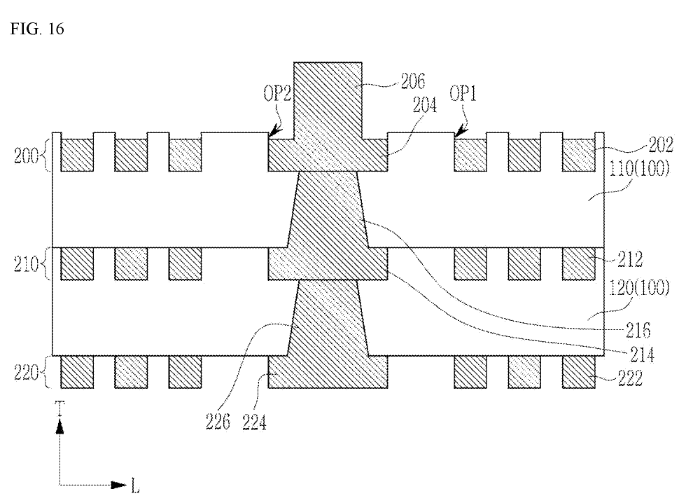

Referring to FIG. 16, the metal barrier layer 80 may be removed.

The metal barrier layer 80 may include a different metal from the protruding pattern 206 and the first wiring layer 200. Accordingly, the metal barrier layer 80 may be selectively removed using an etchant.

A sidewall of the first circuit wiring 202 may be embedded in the insulating layer 100 and the upper surface of the first circuit wiring 202 may not be embedded. According to an example, the upper surface of the first circuit wiring 202 may be disposed at a position indented into the insulating layer 100 from the upper surface of the insulating layer 100. Thus, a first opening OP1 may be formed between the upper surface of the insulating layer 100 and the upper surface of the first circuit wiring 202.

According to an example, the upper surface of the connection pad 204 may be disposed at a position indented into the insulating layer 100 from the upper surface of the insulating layer 100. Accordingly, a second opening OP2 may be formed between the upper surface of the insulating layer 100 and the upper surface of the connection pad 204. The second opening OP2 may be formed along the upper surface of the connection pad 204 and the sidewalls of the protruding pattern 206.

The first opening OP1 and the second opening OP2 may indicate a recess formed in a space from which the metal barrier layer 80 is removed.

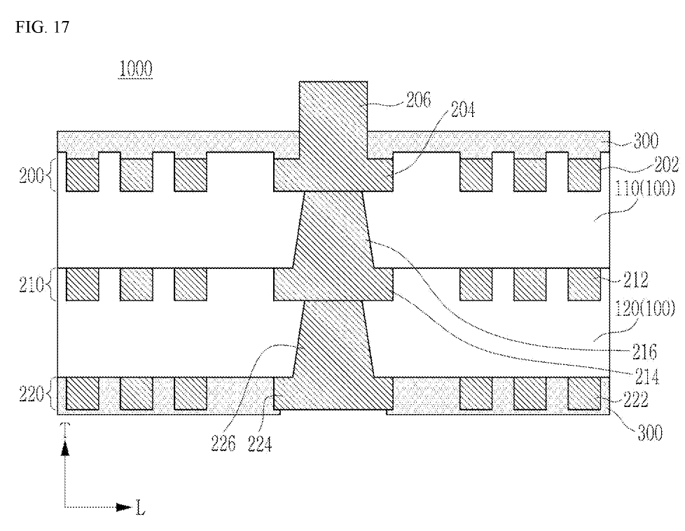

Referring to FIG. 17, the solder resist layer 300 may be formed on the upper surface of the insulating layer 100. The solder resist layer 300 may also be formed on the lower surface of the insulating layer 100.

A solder resist layer 300 may be formed on the upper surface of the insulating layer 100 to expose the upper surface of the protruding pattern 206 by applying and thinning a solder resist. The solder resist layer 300 exposing at least a portion of the lower surface of the lower pad 224 may be formed on the lower surface of the insulating layer 100.

The solder resist layer 300 may cover the first opening OP1 and the second opening OP2. The solder resist layer 300 may cover at least a portion of the upper surface of the connection pad 204 and at least a portion of the sidewall of the protruding pattern 206.

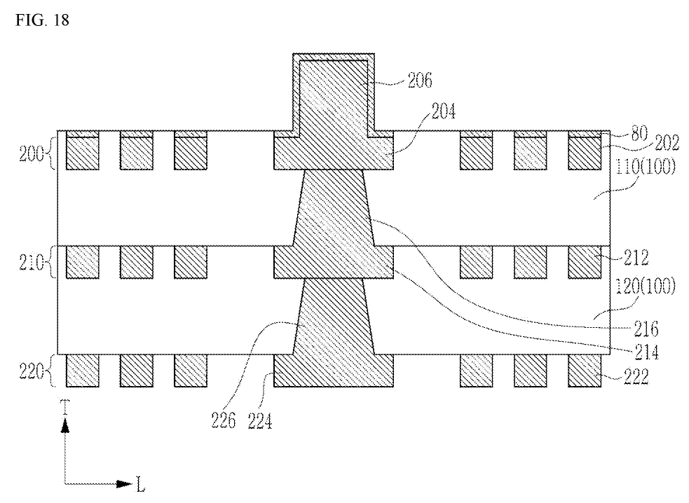

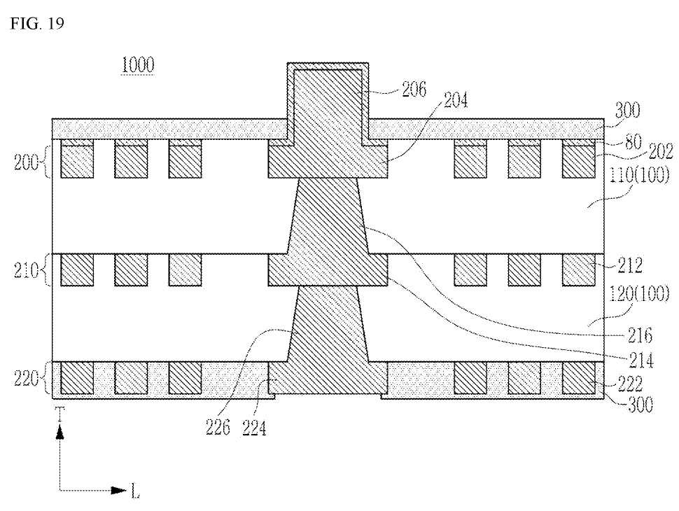

FIGS. 18-19 are cross-sectional views illustrating a manufacturing method of a printed circuit board according to another embodiment.

Referring to FIGS. 18 and 19, the metal barrier layer 80 may not be removed, and the solder resist layer 300 may be formed on the metal barrier layer 80.

In this case, the metal barrier layer 80 may be disposed between the upper surface of the connection pad 204 and the solder resist layer 300, between the sidewall of the protruding pattern 206 and the solder resist layer 300, and on the upper surface of the protruding pattern 206. Therefore, the metal barrier layer 80 is disposed on the protruding pattern 206 without an additional process, so that the protruding pattern 206 can be protected in a structure in which solder and the protruding pattern 206 are connected in a manner such as Flip Chip-Ball Grid Array (FC-BGA), Flip Chip-Chip Scale Package (FC-CSP), etc. Accordingly, structural stability and reliability of the printed circuit board 1000 and the electronic component package including the same may be further improved.

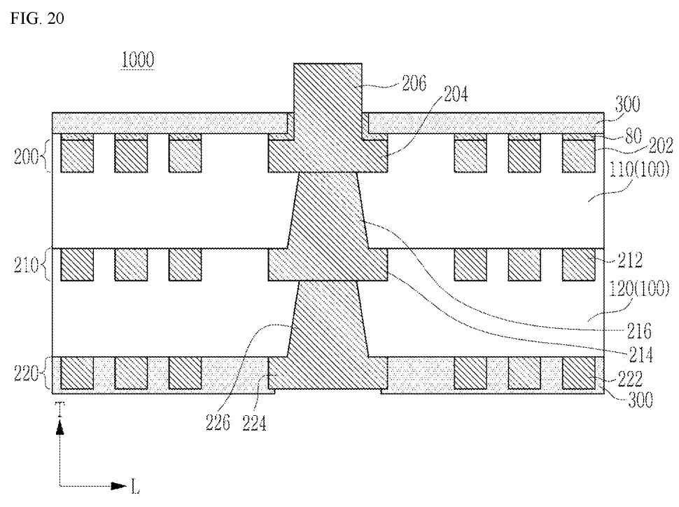

FIG. 20 is cross-sectional view illustrating a manufacturing method of a printed circuit board according to still another embodiment.

Referring to FIG. 20, after the solder resist layer 300 is formed, a portion of the metal barrier layer 80 exposed to the outside may be removed. After forming the solder resist layer 300, the portion of the metal barrier layer 80 exposed to the outside may be selectively removed by using an etchant.

In this case, the metal barrier layer 80 may be disposed between the upper surface of the connection pad 204 and the solder resist layer 300 and between the sidewall of the protruding pattern 206 and the solder resist layer 300. Accordingly, reliability in the drop test of the printed circuit board 1000 may be further improved.

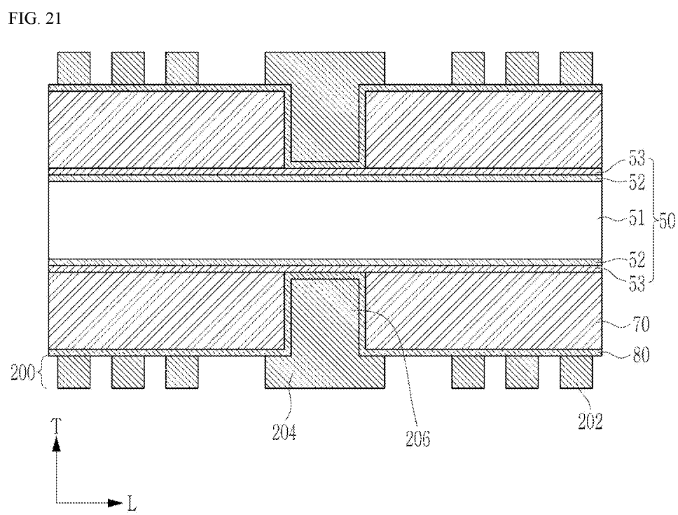

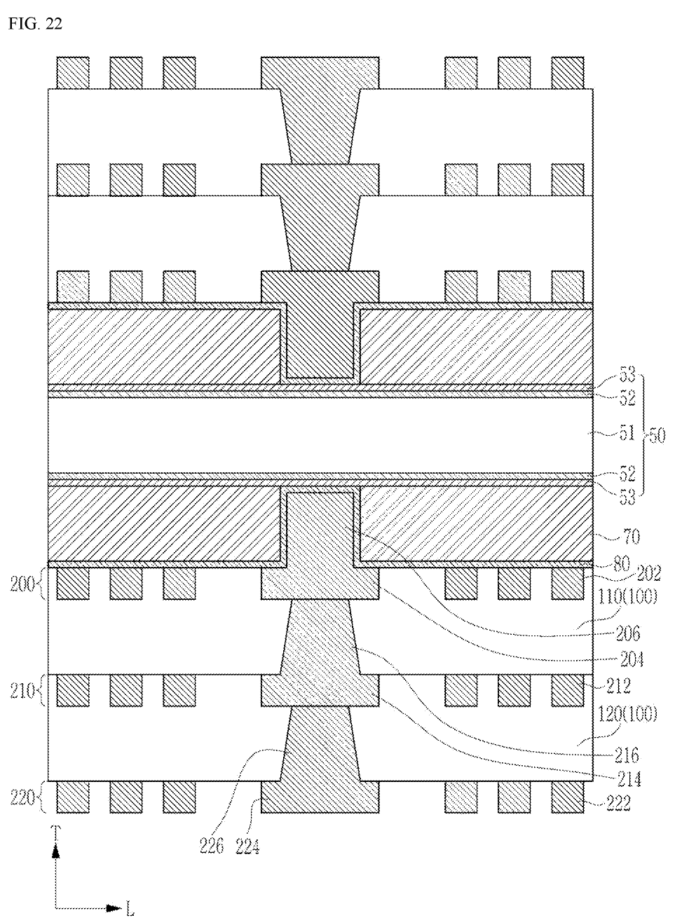

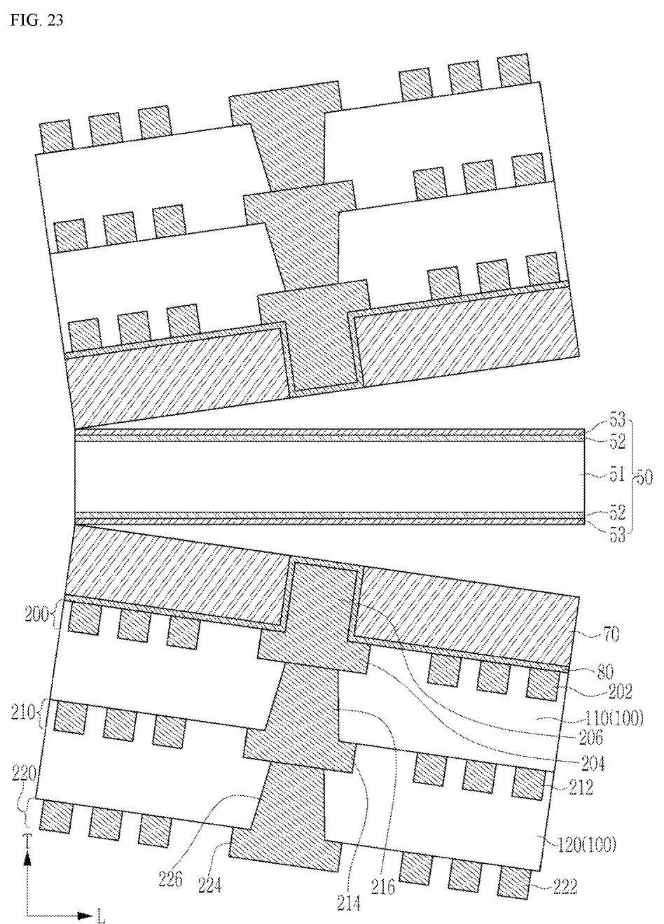

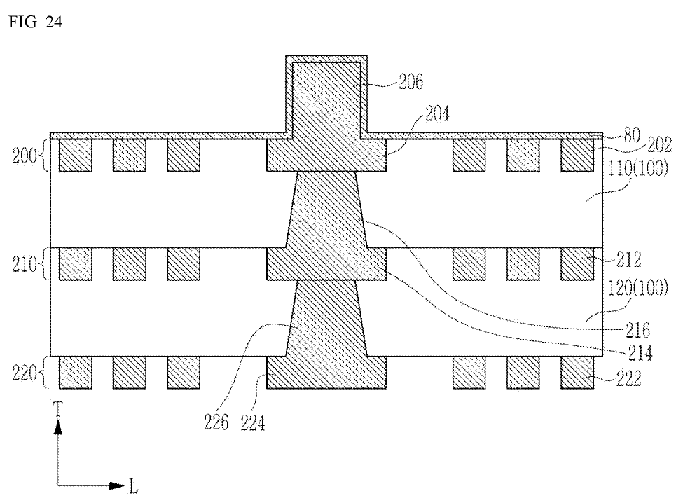

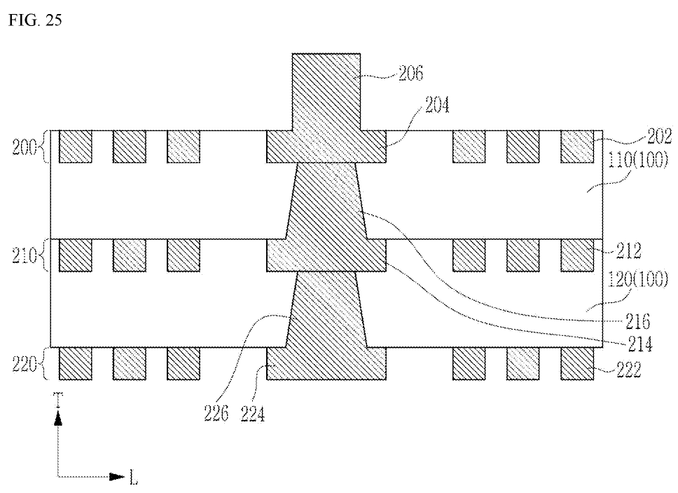

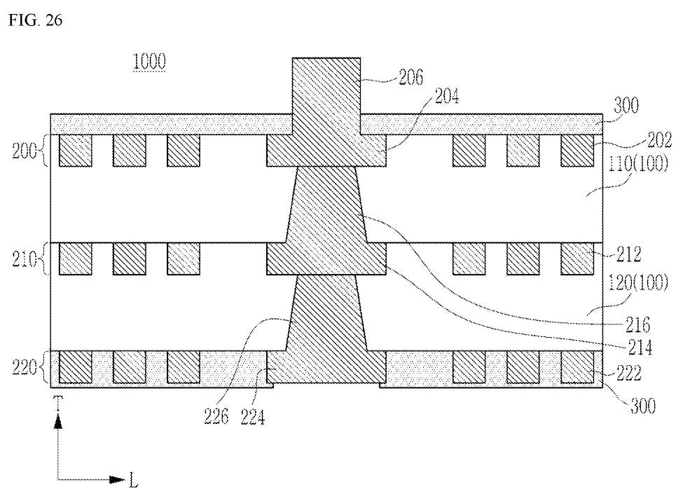

FIGS. 21-26 are cross-sectional views illustrating a manufacturing method of a printed circuit board according to still another embodiment.

Referring to FIGS. 21-26, immediately after the formation of the first wiring layer 200 and the protruding pattern 206, a portion of the metal barrier layer 80 exposed to the outside may not be removed. In this case, the openings OP1 and OP2 may not be formed when the metal barrier layer 80 is etched after the dummy layer 70 is removed.

In an example, the upper surface of the insulating layer 100 and the upper surface of the connection pad 204 may be disposed at the same level. For example, the length L3 from the lower surface of the connection pad 204 to the upper surface of the connection pad 204 may be substantially the same as the length L2 from the lower surface of the connection pad 204 to the upper surface of the insulating layer 100. Accordingly, the printed circuit board 1000 having no recess and an ETS structure may be provided.

In processes such as Thermal Compression-Non Conductive Paste (TC-NCP) and Thermal Compression-Non Conductive Film (TC-NCF) depending on the structure without the recess, a filler may be prevented from entering the openings OP1 and OP2 and/or the recess to interfere with the underfill flow. Accordingly, stability of the printed circuit board 1000 may be further improved and process reliability may be further improved.

What is claimed is:

1. A printed circuit board comprising:
an insulating layer;
a connection pad with a side surface embedded in the insulating layer;
a protruding pattern disposed on a first surface of the connection pad and integral with the connection pad; and
a solder resist layer disposed on the insulating layer, and covering at least a portion of the first surface of the connection pad and at least a portion of a side surface of the protruding pattern.

2. The printed circuit board of claim 1, wherein:
a second surface of the connection pad directly contacts the insulating layer.

3. The printed circuit board of claim 1, wherein:
at least a portion of the first surface of the connection pad is not embedded in the insulating layer.

4. The printed circuit board of claim 1, wherein:
a length from a second surface of the connection pad to a first surface of the protruding pattern in a thickness direction perpendicular to a first surface of the insulating layer is greater than a length from the second surface of the connection pad to the first surface of the insulating layer.

5. The printed circuit board of claim 1, wherein:
a width of the protruding pattern is less than or equal to a width of the connection pad.

6. The printed circuit board of claim 5, wherein:
a ratio of the width of the protruding pattern to the width of the connection pad is 0.9 to 1.0.

7. The printed circuit board of claim 1, further comprising:
a metal barrier layer disposed between the first surface of the connection pad and the solder resist layer, and between the side surface of the protruding pattern and the solder resist layer.

8. The printed circuit board of claim 7, wherein:
the metal barrier layer is further disposed on a first surface of the protruding pattern.

9. The printed circuit board of claim 1, wherein:
a length from a second surface of the connection pad to the first surface of the connection pad in a thickness direction perpendicular to a first surface of the insulating layer is less than or equal to a length from the second surface of the connection pad to the first surface of the insulating layer.

10. The printed circuit board of claim 1, wherein:
a first surface of the insulating layer and the first surface of the connection pad are disposed at the same level.

11. The printed circuit board of claim 1, further comprising:
a metal barrier layer disposed only (i) between the first surface of the connection pad and the solder resist layer, and (ii) between the side surface of the protruding pattern and the solder resist layer.

12. A manufacturing method of a printed circuit board comprising:
forming a dummy layer on a carrier substrate, the dummy layer defining a cavity that exposes a portion of the carrier substrate,
forming a metal barrier layer on the dummy layer, and the portion of the carrier substrate,
forming:
a protruding pattern filling the cavity, and
a first wiring layer comprising a connection pad, where the connection pad and the protruding pattern are formed together on the metal barrier layer,
forming a build-up structure on the dummy layer and the first wiring layer, the build-up structure comprising an insulating layer and an inner wiring layer,
separating the build-up structure and the dummy layer from the carrier substrate,
removing the dummy layer, and
forming a solder resist layer covering at least a portion of a first surface of the connection pad and at least a portion of a side surface of the protruding pattern on a first surface of the insulating layer.

13. The manufacturing method of claim 12, further comprising:
after the forming of the protruding pattern and the first wiring layer, removing an exposed portion of the metal barrier layer .

14. The manufacturing method of claim 12, further comprising:
after the removing of the dummy layer and before the forming the solder resist layer, removing the metal barrier layer.

15. The manufacturing method of claim 12, further comprising:
after the forming of the solder resist layer, removing an exposed portion of the metal barrier layer .

16. The manufacturing method of claim 12, wherein:
the first surface of the insulating layer and the first surface of the connection pad are disposed at the same level.

17. The manufacturing method of claim 12, wherein:
the connection pad and the protruding pattern are formed integrally through a single process.

18. The manufacturing method of claim 12, wherein:
after the forming of the solder resist layer, an exposed portion of the metal barrier layer is not removed.

19. The manufacturing method of claim 12, wherein:
the metal barrier layer includes nickel (Ni).
